(19) United States
(12) Patent Application Publication
(10) Pub. No.: US 2008/0101085 A1
(43) Pub. Date: May 1, 2008

(54) Display Device, Backlight Module, and Packaging Structure of Light Emitting Diode

(75) Inventors: Chieh-Hsiu Lin, Hsin-Chu (TW); Wu-Sheng Chi, Hsinchu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU OPTRONICS CORP., Hsinchu (TW)

(21) Appl. No.: 11/738,751

(22) Filed: Apr. 23, 2007

(30) Foreign Application Priority Data
Oct. 30, 2006 (TW) 95140024

(51) Int. Cl. F21V 23/00; H01L 33/00

(52) U.S. Cl. 362/612; 257/99; 257/E33.066

(57) ABSTRACT

A display device comprises a power supply module and a back-lit module. The power supply module provides power and the back-lit module comprises a plurality of light emitting diode packaging structure in series. At least one light emitting diode packaging structure comprises two lead frames, a light emitting diode unit, and a regulator. The light emitting diode unit is connected to the two lead frames and the connection forms a first current path. The regulator is connected to the two lead frames and the connection forms a second current path. When the light emitting diode operates normally, the current generated by the power passes through the first current path. Otherwise, the current passes through the second current path.

### CROSS-REFERENCES TO RELATED APPLICATIONS

This application claims the benefit of priority based on Taiwan Patent Application No. 095140024 filed on Oct. 30, 2006 of which the contents are incorporated herein by reference in its entirety.

### BACKGROUND OF THE INVENTION

1. Field of the Invention

The present invention relates to a display device, a backlight module, and a package structure of a light emitting diode; specifically to a display device, a backlight module, and a package structure of a light emitting diode for preventing the malfunction of a series of light emitting diodes due to the failure of a single light emitting diode.

2. Descriptions of the Related Art

A light emitting diode has the advantages of small size, fast response time, long service life, anti-decaying properties, a rigid surface, immunity to vibration, full color emission (including invisible light), easy directing design, low voltage requirement, low current draw, low transformation loss, less heat radiation, and easy mass production. Additionally, light emitting diodes are environmentally friendly. Therefore, light emitting diodes are widely adapted for various applications such as traffic lights, flashlights, and the lamps of a backlight module for a liquid crystal display.

FIG. 1 depicts a conventional light emitting diode packaging structure 1 which comprises three light emitting diode chips 12, 13, and 14, for generating red, green, and blue colors. Using a red light emitting diode chip 12 as an example, a current path is formed by connecting the two lead frames 10 and 11. While the light emitting diode chip 12 operates normally, the current through the current path turns on the light emitting diode chip 12, wherein the lead frame 10 is electrically connected with a pin 15 of the light emitting diode packaging structure 1 and the lead frame 11 is electrically connected with a pin 16 of the light emitting diode packaging structure 1. The connection method between the other two light emitting diode chips 13 and 14 and the pins of corresponding lead frames thereof is the same as that of the light emitting diode chip 12, and thus no unnecessary details are given.

When the light emitting diode packaging structure 1 is applied on a flat panel display, each lamp of the flat panel display usually comprises a plurality of light emitting diode packaging structures 1 in series. FIG. 2 depicts a plurality of cascaded light emitting diode packaging structures 2 comprising a plurality of light emitting diode packaging structure 1 in series. For a more detailed description, the pin 16 of the light emitting diode packaging structure 1 of a previous stage is connected with the pin 15 of the light emitting diode packaging structure 1 of a following stage. If the light emitting diode chip 12 of one light emitting diode packaging structure 1 of the cascaded light emitting diode packaging structure 20 is abnormal, the current path will be broken due to the abnormality of the light emitting diode chip 12, which prevents the cascaded light emitting diode packaging structure 2 from being electrified and thus loses the function of emitting red light.

According to the mentioned descriptions, if a light emitting diode chip malfunctions, the whole light emitting diode packaging structure in series will be affected. Therefore, constructing a light emitting diode packaging structure in series that operates normally without being affected by a single abnormal light emitting diode chip is still an objective for the industry to endeavor.

### SUMMARY OF THE INVENTION

The primary objective of this invention is to provide a light emitting diode packaging structure which comprises two lead frames, a light emitting diode unit and a stabilization device. The light emitting diode unit is connected to the two lead frames to form a first current path. The stabilization device is also connected to the two lead frames to form a second current path. When the light emitting diode unit operates normally, the current passes through the first current path. Otherwise, the current passes the second current path.

Another objective of this invention is to provide a backlight module which comprises a plurality of light emitting diode packaging structure in series. At least one of the light emitting diode packaging structure comprises two lead frames, a light emitting diode unit and a stabilization device. The light emitting diode unit is connected to the two lead frames to form a first current path. The stabilization device is also connected to the two lead frames to form a second current path. When the light emitting diode unit operates normally, the current passes through the first current path. If the light emitting diode unit operates abnormally, the current passes through the second current path.

Yet another objective of this invention is to provide a display device comprising a power supply module and a backlight module. The power supply module is used for supplying a current and the backlight module comprises a plurality of the light emitting diode packaging structure in series. At least one light emitting diode packaging structure comprises two lead frames, a light emitting diode unit and a stabilization device. The light emitting diode unit is connected to the two lead frames to form a first current path. The stabilization device is also connected to the two lead frames to form a second current path. When the light emitting diode unit operates normally, the current passes through the first current path. If the light emitting diode unit operates abnormally, the current passes through the second current path.

With the mentioned arrangement, this invention can prevent the malfunction of a plurality of light emitting diodes in series due to the failure of a single light emitting diode.

The detailed technology and preferred embodiments implemented for the subject invention are described in the following paragraphs accompanying the appended figures for those skilled in this field to well appreciate the features of the claimed invention.

### BRIEF DESCRIPTION OF THE FIGURES

FIG. 1 is a diagram of a conventional light emitting diode packaging structure;

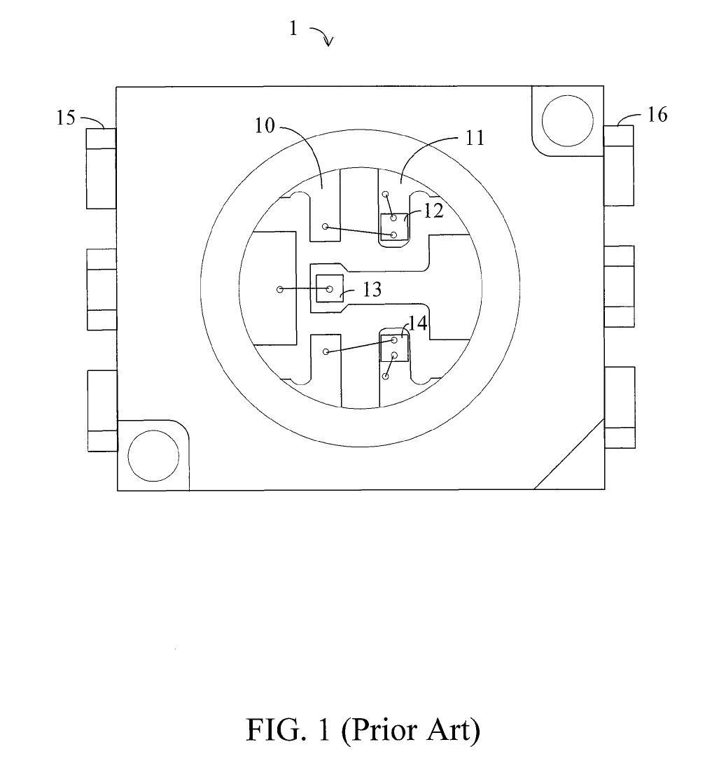

FIG. 2 is a diagram of a conventional plurality of light emitting diode packaging structure in series;

FIG. 3 is a diagram of a display device of the present invention; and

FIG. 4 is a diagram of a light emitting diode packaging structure of the present invention.

### DESCRIPTION OF THE PREFERRED EMBODIMENT

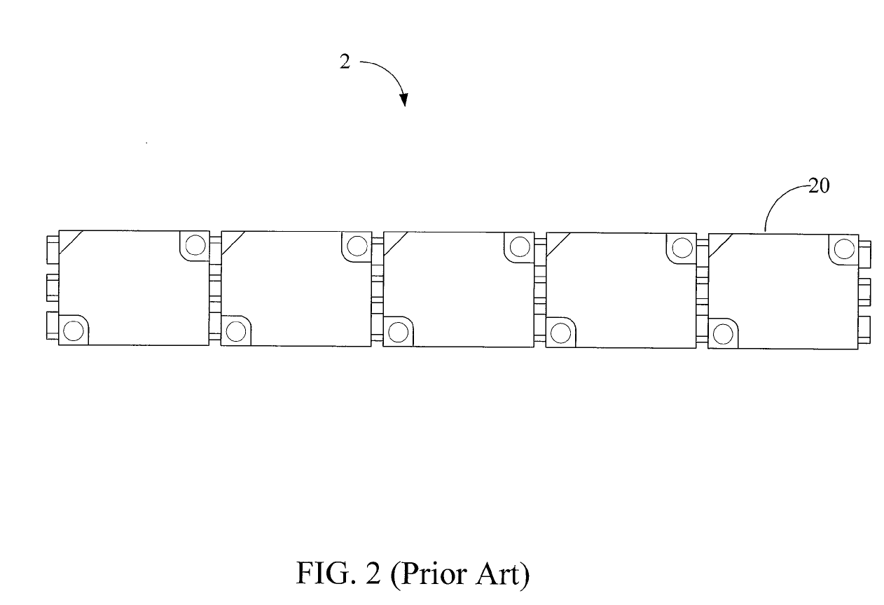

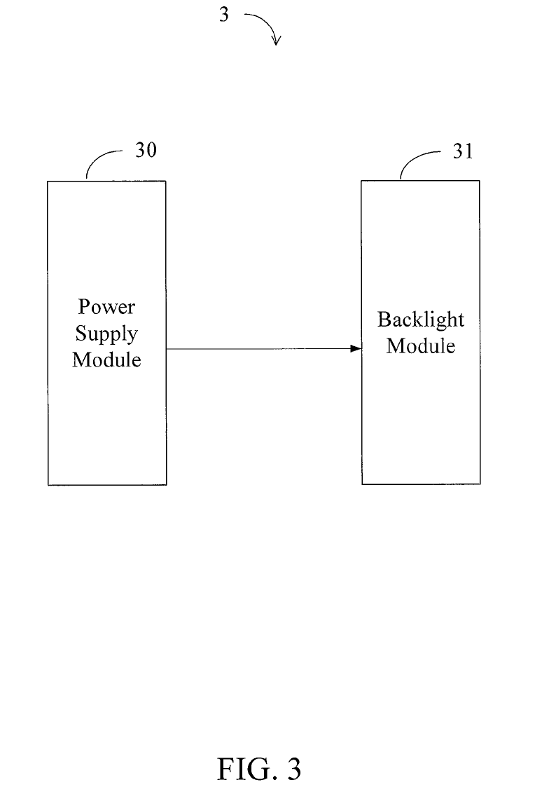

An embodiment of this invention as depicted in FIG. 3 is a display device 3. The display device 3 comprises a power supply module 30 and a backlight module 31. The power supply module 30 is used for supplying the current for the backlight module 31 which comprises a plurality of lamps. Each of these lamps comprises a plurality of light emitting diode packaging structures in series as depicted in FIG. 2 to generate light.

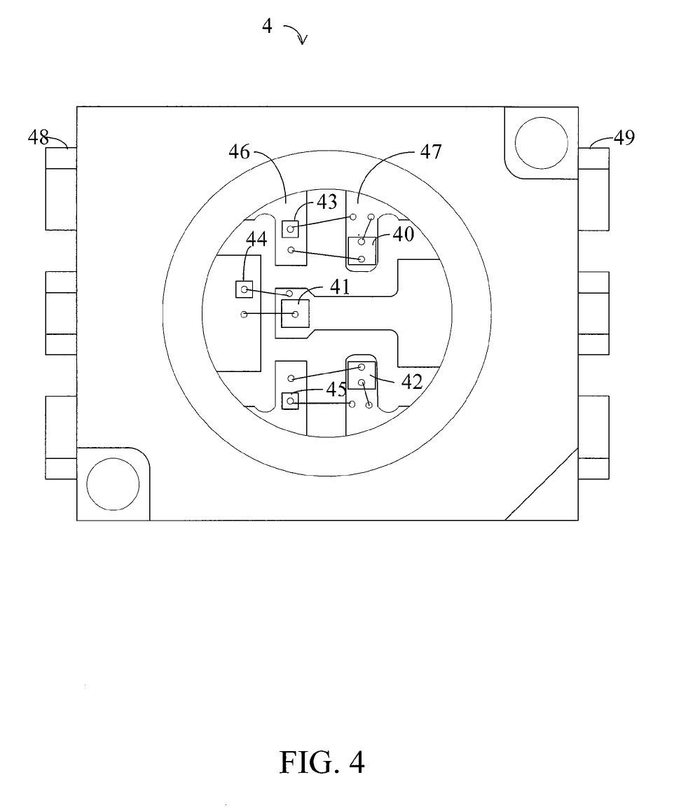

As depicted in FIG. 4, each light emitting diode packaging structure 4 comprises three light emitting diode units 40, 41, and 42, and three stabilization devices 43, 44, and 45. Similarly, the light emitting diode units 40, 41, and 42 respectively generate a red, a green and a blue color. Using the light emitting diode unit 40 as an example, the light emitting diode unit 40 is connected to two metal lead frames 46 and 47 to form a first current path. The stabilization device 43 also connects to the two metal lead frames 46 and 47 to form a second current path, wherein the lead frame 46 is electrically connected with the pin 48 of the light emitting diode packaging structure 4 and the lead frame 47 is electrically connected with the pin 49 of the light emitting diode packaging structure 4. When the light emitting diode unit 40 operates normally, the current supplied by the power supply module 30 passes through the first current path and turns on the light emitting diode unit 40. If the light emitting diode unit 40 operates abnormally, the current supplied by the power supply module 30 passes through the second current path. Although the light emitting diode unit 40 is abnormal, the light emitting from the other light emitting diode units on the same lamp will not be affected. When the current passes through the second current path, the stabilization device 43 provides a voltage drop.

It shall be noted that the voltage drop of the stabilization device 43 is preferably higher than the voltage drop of the light emitting diode unit 40 to prevent the current from passing through the stabilization device 43 even if the light emitting diode unit 40 is operating normally. Generally speaking, the operating voltage of the red light emitting diode unit is from 1.8V to 2.3V and the operating voltage of the green and blue light emitting diode unit is from about 2.8V to 3.4V. Consequently, the voltage drop of the stabilization device 43 can be from 2V to 5V, but is not limited within this range. For a more detailed description, the stabilization device 43 can be, but is not limited to, a voltage regulator or a Zener diode. When the current passes through the second current path and the stabilization device 43 is a Zener diode, the Zener diode operates in a reverse bias mode to generate the mentioned fixed voltage drop.

The connection way between the light emitting diode units 41 and 42 and the stabilization devices 44 and 45 is the same as the example given for the light emitting diode unit 40, and thus no unnecessary details are given. Although this embodiment shows an example of a single light emitting diode unit which emits light in a single color, a light emitting diode unit which is able to emit light in multiple colors already appears in the market. Those skilled in this art may easily apply a light emitting diode of multiple colors according to the descriptions of this embodiment.

According to the mentioned descriptions, when a light emitting diode unit of a backlight module operates abnormally, the current will not be affected so that the current of the whole backlight module still flows. Consequently, this invention can solve the problem of the plurality of light emitting diodes in series malfunctioning due to the failure of one single light emitting diode.

The above disclosure is related to the detailed technical contents and inventive features thereof. Those skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A light emitting diode packaging structure comprising:
two lead frames;
a light emitting diode unit for connecting to the two lead frames and forming a first current path after connection; and
a stabilization device for connecting to the two lead frames and forming a second current path after connection;
wherein a current passes the first current path while the light emitting diode unit operates normally, otherwise the current passes the second current path.

2. The light emitting diode packaging structure according to claim 1, wherein the light emitting diode unit comprises one or a combination of a blue light emitting diode, a red light emitting diode and a green light emitting diode.

3. The light emitting diode packaging structure according to claim 1, wherein the stabilization device comprises a Zener diode.

4. The light emitting diode packaging structure according to claim 3, wherein the Zener diode operates in a reverse bias while the current passes the second path.

5. The light emitting diode packaging structure according to claim 4, wherein a range of the reverse bias is from 2V to 5V.

6. The light emitting diode packaging structure according to claim 1, wherein the stabilization device is a voltage regulator.

7. A backlight module comprising a plurality of light emitting diode packaging structures in series, at least one of the light emitting diode packaging structures comprising:
two lead frames;
a light emitting diode unit, the light emitting diode unit being connected to the two lead frames to form a first path; and
a stabilization device, the stabilization device being connected to the two lead frames to form a second path;
wherein the current passes the first path while the light emitting diode unit operates normally, and the current passes the second path while the light emitting diode unit operates abnormally

8. The backlight module according to claim 7, wherein the light emitting diode unit comprises one or a combination of a blue light emitting diode, a red light emitting diode and a green light emitting diode.

9. The backlight module according to claim 7, wherein the stabilization device comprises a Zener diode.

10. The backlight module according to claim 9, wherein the Zener diode operates in a reverse bias while the current passes the second path.

11. The backlight module according to claim 10, wherein a range of the reverse bias is from 2V to 5V.

12. The backlight module according to claim 7, wherein the stabilization device comprises a voltage regulator.

13. A display apparatus, comprising:
a power supply module for supplying a current;
a backlight module comprising a plurality of light emitting diode packaging structures in series, at least one of the light emitting diode packaging structures comprising:
two lead frames;
a light emitting diode unit, the light emitting diode unit being connected to the two lead frames to form a first path; and
a stabilization device, the stabilization device being connected to the two lead frames to form a second path;
wherein the current passes the first path while the light emitting diode unit operates normally, and the current passes the second path while the light emitting diode unit operates abnormally.

14. The display apparatus according to claim 13, wherein the light emitting diode unit comprises one or a combination of a blue light emitting diode, a red light emitting diode and a green light emitting diode.

15. The display apparatus according to claim 13, wherein the stabilization device comprises a Zener diode.

16. The display apparatus according to claim 15, wherein the Zener diode operates in a reverse bias while the current passes the second path.

17. The display apparatus according to claim 16, wherein a range of the reverse bias is from 2V to 5V.

18. The display apparatus according to claim 13, wherein the stabilization device is a voltage regulator.
